(19) United States
(12) Patent Application Publication
(10) Pub. No.: US 2015/0047971 A1
(43) Pub. Date: Feb. 19, 2015

(54) SPUTTERING TARGET, METHOD OF MANUFACTURING SPUTTERING TARGET, METHOD OF MANUFACTURING BARIUM TITANATE THIN FILM, AND METHOD OF MANUFACTURING THIN FILM CAPACITOR

(71) Applicant: Sony Corporation, Tokyo (JP)

(72) Inventors: Kiwamu Adachi, Kanagawa (JP); Shusaku Yanagawa, Kanagawa (JP)

(73) Assignee: Sony Corporation, Tokyo (JP)

(21) Appl. No.: 14/387,027

(22) PCT Filed: Feb. 25, 2013
(86) PCT No.: PCT/JP2013/054696

§ 371 Date: Sep. 22, 2014

(30) Foreign Application Priority Data
Apr. 2, 2012 (JP) 2012-084057

(51) Int. Cl. C23C 14/34; C04B 35/64; C04B 35/468; H01J 37/34; C23C 14/06

(52) U.S. Cl. CPC C23C 14/3414; H01J 37/3426; C23C 14/06; C04B 35/4682; C04B 35/64; H01J 2237/332
USPC 204/192.15; 204/298.13; 264/603

(57) ABSTRACT

A sputtering target includes a conductive barium titanate sintered material with generation density of crystal grain aggregate (12) having a grain diameter of 10 μm or more on a cleavage surface of less than 0.2 piece/cm².

### TECHNICAL FIELD

The present technology relates to a sputtering target, and in particular, to a sputtering target that is used for sputtering film formation of a high dielectric thin film on a substrate and has a conductive barium titanate target sintered material. Further, the present technology relates to a method of manufacturing the sputtering target, a method of manufacturing a barium titanate thin film using the sputtering target, and a method of manufacturing a thin film capacitor using the sputtering target.

### BACKGROUND ART

At the time of forming a perovskite type high dielectric thin film used for a thin film capacitor, film has been formed by high-frequency sputtering using an insulating sputtering target. However, since the sputtering target has an insulating property, disadvantageously, a sputter rate is low and productivity is remarkably impaired. In addition, since a high-frequency power source is used for the sputtering, it is difficult to increase size of a sputtering apparatus, and film formation on a large substrate is disadvantageously difficult.

Therefore, a conductive sputtering target has been proposed in order to increase a sputter rate, or to be applied to a sputtering apparatus using a low-frequency power source.

As an example of such a conductive sputtering target, a sputtering target that is a ceramic material causing oxygen deficient at the time of firing and whose electric resistance in a plate thickness direction of the target measured at the application voltage of 1.5 V is within a range of 100 mΩ·cm to 10 ∩·cm has been disclosed. For example, a sputtering target formed of composition of BaTiO_{3-X} may be manufactured in such a manner that BaTiO₃ powder is used as the ceramic material, and the powder is fired by hot pressing method at 1300° C. in vacuum (see PTL1 described below).

Moreover, as another example of the conductive sputtering target, a sputtering sintered target material that is formed of a composite oxide of Ba and Ti and in which oxygen content in the composite oxide is lower by 4.9 to 10% than a theoretical oxygen content has been disclosed. The sputtering sintered target material is fabricated in the following manner. First, the BaTiO₃ powder is subjected to oxygen reducing heating treatment in vacuum or in reducing atmosphere under a condition of temperature of 1200 to 1450° C. and predetermined time retention, to reduce oxygen content in the powder. Subsequently, the powder is ground and dried, and then hot pressing is performed on the powder in vacuum under the condition of temperature of 1250 to 1350° C., pressure of 200 kgf/cm², and retention time of three hours. As a result, the sputtering sintered target material is fabricated (see PTL 2 described below).

### CITATION LIST

### Patent Literature

PTL 1: Japanese Patent No. 3464251
PTL 2: Japanese Patent No. 3129046

### SUMMARY OF INVENTION

However, to fabricate the conductive sputtering target by the oxygen deficient as described above, it is necessary to sinter the target material at higher temperature than that of the insulating sputtering target. Accordingly, a part of the target material is molten and recrystallized at the time of sintering, and thus a crystal grain aggregate having a large diameter is formed in the target material. When such a sputtering target containing the crystal grain aggregate is used for the low-frequency sputtering, local electrostatic charging occurs at the part of the crystal grain aggregate, which disadvantageously causes arcing because the crystal grain aggregate is different from the surrounding crystals in terms of a dielectric constant and resistivity. Further, since the crystal grain aggregate is different from the surrounding crystals in terms of thermal expansion coefficient, thermal stress occurs, which may cause damage of the target material or the like. Accordingly, the above-described conductive sputtering target is not allowed to be applied to the low-frequency sputtering.

Therefore, it is desirable to provide a sputtering target that is capable of preventing occurrence of arcing, damage of a target material, and the like in low-frequency sputtering, and is applicable to a large sputtering apparatus using a low-frequency power source. In addition, it is desirable to provide a method of manufacturing such a sputtering target, a method of manufacturing a barium titanate thin film, and a method of manufacturing a thin film capacitor.

A sputtering target according to an embodiment of the present technology for achieving such a purpose includes a conductive barium titanate sintered material with generation density of crystal grain aggregate having a grain diameter of 10 μm or more on a cleavage surface of less than 0.2 piece/cm².

In the sputtering target having such a structure, the generation density of the crystal grain aggregate is less than 0.2 pieces/cm². In other words, the number of the crystal grain aggregates that cause occurrence of arcing, damage of a target material, and the like is extremely small.

Moreover, a method of manufacturing a sputtering target according to an embodiment of the technology also serves as a method of manufacturing the above-described sputtering target, and includes performing primary firing of barium titanate (BaTiO₃) powder in air atmosphere, and performing hot pressing of the fired barium titanate (BaTiO₃) powder after the primary firing.

Moreover, a method of manufacturing a barium titanate thin film according to an embodiment of the technology also serves as a method of manufacturing a barium titanate thin film using the above-described sputtering target. Further, a method of manufacturing a thin film capacitor according to an embodiment of the technology also serve as a method of manufacturing a thin film capacitor using the above-described sputtering target.

In the above-described sputtering target according to the embodiment of the disclosure, the generation density of the crystal grain aggregate on a cleavage surface of a barium titanate sintered material is less than 0.2 piece/cm². Therefore, it is possible to prevent occurrence of arcing, damage of the target material, and the like when the sputtering target is used in low-frequency sputtering. As described above, the sputtering target according to the embodiment of the technology is allowed to be applied to the low-frequency sputtering. Further, the sputtering target according to the embodiment of the technology is applicable to a large sputtering apparatus using a low-frequency power source, which makes it possible to manufacture a thin film capacitor using a large substrate.

### BRIEF DESCRIPTION OF DRAWINGS

FIG. 1 is an image of a sputtering target according to a first embodiment, that is observed by a stereoscopic microscope.

FIG. 2A is an image of a comparative sputtering target, that is observed by a stereoscopic microscope.

FIG. 2B is an enlarged image of the image of FIG. 2A.

FIG. 3 is a flowchart illustrating a method of manufacturing the sputtering target according to the first embodiment.

FIG. 4 is a cross-sectional schematic diagram illustrating a structure of a thin film capacitor according to a third embodiment.

FIG. 5 is a cross-sectional schematic diagram illustrating a circuit substrate incorporated with the thin film capacitor according to the third embodiment.

FIG. 6 is a graph illustrating variation of resistivity in a thickness direction of sputtering target samples No. 3 and No. 64 fabricated in Example 1.

FIG. 7 is a graph illustrating reproducibility of a sputter rate using the sputtering target sample No. 64 fabricated in Example 1.

### DESCRIPTION OF EMBODIMENTS

Hereinafter, some embodiments of the technology will be described in the following order with reference to drawings.

1. First Embodiment: a target material with generation density of a crystal grain aggregate of less than 0.2 piece/cm²
2. Second Embodiment: a method of manufacturing a barium titanate thin film
3. Third Embodiment: a method of manufacturing a thin film capacitor
Note that same numerals are used to designate components common to the embodiments, and overlapped description is omitted.

### 1. First Embodiment

### A Target Material with Generation Density of Crystal Grain Aggregate of Less than 0.2 piece/cm²

### <1-1. Structure of Sputtering Target>

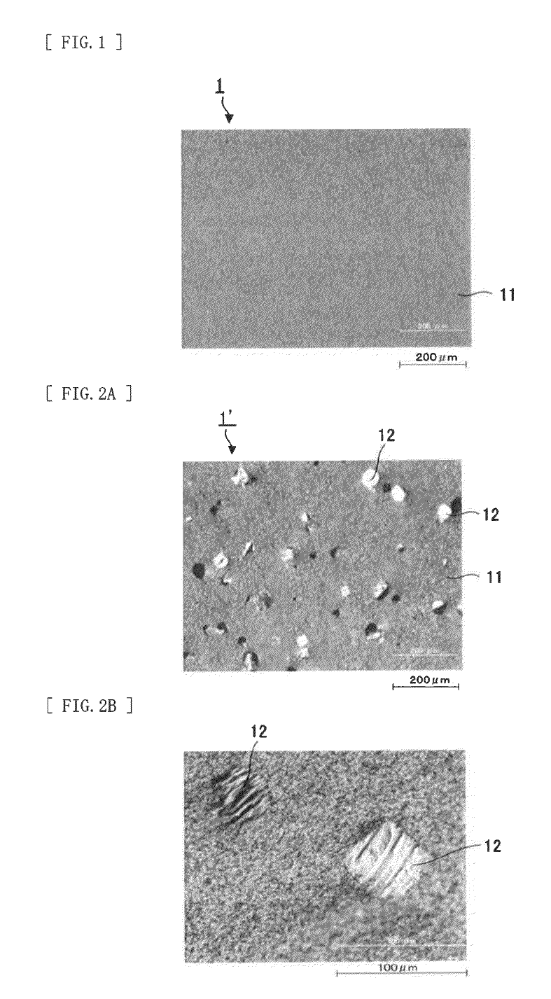

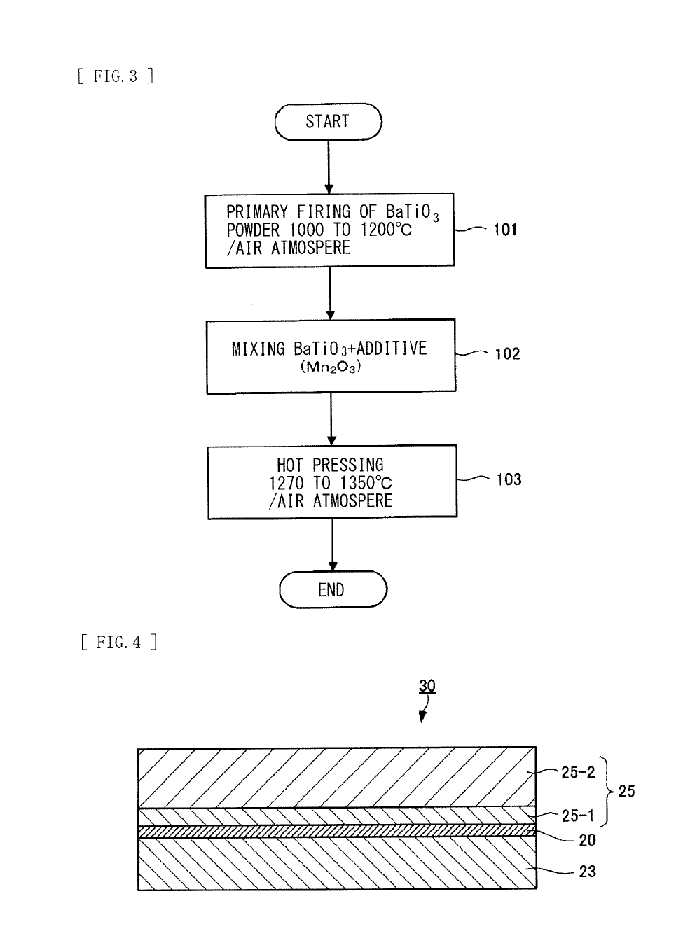

FIG. 1 is an image (at a magnification of 50 times) of a cleavage surface of a barium titanate sintered material of a sputtering target (hereinafter, referred to as target material) to which the present technology is applied, that is observed by a stereoscopic microscope. FIG. 2A is an image (at a magnification of 50 times) of a cleavage surface of a comparative target material, that is observed by a stereoscopic microscope, and FIG. 2B is an enlarged diagram thereof (at a magnification of 200 times).

The sputtering target of the first embodiment to which the present technology is applied includes a plate-like conductive target material 1. The target material 1 is formed of microcrystals 11 as a main crystal component, and a small number of crystal grain aggregates 12 may be dispersed in a lot of microcrystals 11. The observed image of the cleavage surface of such a target material 1 is illustrated in FIG. 1. Further, the target material 1 in the case where a small number of crystal grain aggregates 12 are dispersed is a barium titanate sintered material with generation density of the crystal grain aggregate 12 of less than 0.2 pieces/cm² on the cleavage surface.

(Microcrystal 11)

The microcrystal 11 is a crystal component mainly configuring the target material 1, and the composition thereof is barium titanate. An average particle diameter of the microcrystals 11 is about 0.5 to 3 μm. Moreover, the microcrystal 11 is formed in such a manner that barium titanate powder is pressurized and sintered without melting in the hot pressing process in manufacturing the sputtering target, and roughly maintains the size of the powder before the hot pressing.

(Crystal Grain Aggregate 12)

A small number of crystal grain aggregates 12 may be dispersed in the target material 1, and the composition of the crystal grain aggregate 12 is barium titanate, similar to the surrounding microcrystals 11. The crystal grain aggregate 12 is formed in such a manner that the barium titanate powder partially melts and is recrystallized at the time of hot pressing in the manufacturing process of the sputtering target. The size of the crystal grain aggregate 12 is larger than that of the microcrystal 11, has a grain diameter of 10 μm or more, and specifically, has a grain diameter of about 10 to 80 μm. Incidentally, when the crystal grain aggregate having a grain diameter of 80 μm or more is confirmed in a target material, the target material is not included in the target material 1 according to the embodiment of the present technology, irrespective of generation density.

(Generation Density of Crystal Grain Aggregate 12)

A method of calculating the generation density of the crystal grain aggregate 12 described above is then described. The target material 1 is cleft in a random manner, the cleavage surface is observed by a stereoscopic microscope (at a magnification of 50 times to 100 times), and the number of crystal grain aggregates 12 is counted. At this time, only one of a pair of cleavage surfaces generated by cleaving is observed. For example, the target material 1 is cleft several times in a random manner, and a plurality of pairs of cleavage surfaces thus generated are observed by the stereoscopic microscope over the range of total of 50 cm². In this observation, when 10 pieces of crystal grain aggregates 12 having a grain diameter of 10 to 80 μm that is recognizable by stereoscopic microscope observation at a magnification of 50 times to 100 times are confirmed, the generation density of the crystal grain aggregate 12 in the cleavage surface of the target material 1 is 0.2 piece/cm². The sputtering target of the first embodiment includes the target material 1 in which the generation density of the crystal grain aggregate 12 having the grain diameter of 10 to 80 μm calculated by such observation is less than 0.2 piece/cm². Incidentally, the target member 1 may not preferably contain the crystal grain aggregate 12, namely, the generation density of the crystal grain aggregate 12 may be preferably 0 piece/cm².

In the target material 1 configuring the sputtering target of the first embodiment, the generation density of the crystal grain aggregate 12 is less than 0.2 piece/cm², and therefore, it may be said that there is substantially no crystal grain aggregate 12. On the cleavage surface of the target material 1 illustrated in FIG. 1, the entire surface is formed of the microcrystal 11, and the crystal grain aggregate 12 is not observed. On the other hand, on the cleavage surface of a comparative target material 1′ illustrated in FIG. 2A, a lot of crystal grain aggregates 12 are observed together with the microcrystals 11. As described above, the microcrystal 11 has an average grain diameter of about 0.5 to 3 μm, whereas the crystal grain aggregate 12 has a grain diameter of 10 to 80 μm, and thus the size is obviously different. In addition, as illustrated in the enlarged diagram of FIG. 2B, when the image is magnified to 200 times, the microcrystal 11 and the crystal grain aggregate 12 are different in crystallinity from each other, and the crystal grain aggregates 12 are different in crystal orientation from one another.

(Additives)

Moreover, the sputtering target of the first embodiment may contain manganese (Mn) as an additive. The content of manganese (Mn) is 0.25 atm % or lower with respect to the total amount of barium (Ba) and titanium (Ti) that configure the barium titanate sintered material (the target material 1). In the target material 1 containing the additive, the composition is different between the microcrystal 11 and the crystal grain aggregate 12.

As other examples of the additives, the sputtering target of the first embodiment may contain one or two or more elements selected from silicon (Si), aluminum (Al), magnesium (Mg), vanadium (V), tantalum (Ta), niobium (Nb), and chromium (Cr). Further, the sputtering target of the first embodiment may contain manganese together with the elements.

In addition, the target material 1 may contain an oxide of any of the elements as the additive. For example, the target material 1 may contain manganese oxide (Mn₂O₃) as the additive.

(Conductivity)

Moreover, the target material 1 has resistivity in the thickness direction of 0.1 to 10 Ω·cm. The resistivity indicates that oxygen deficient state of the target material 1 is sufficient. In other words, barium titanate configuring the target material 1 is in the oxygen deficient state, and the composition thereof is BaTiO₃₋ₓ.

Further, in the target material 1, variation of the resistivity in the thickness direction is within ±10%. In other words, when the resistivity of an exposed surface that is formed by scraping the target material 1 in the thickness direction is measured, variation in resistivity of the surface at each thickness is within ±10%. This indicates that the composition of the target material 1 is not varied in the surface and the inside of the target material 1 and is uniform, and the oxygen deficient state is sufficient not only on the surface but also in the inside, in the thickness direction of the target material 1.

### <1-2. Method of Manufacturing Sputtering Target>

Next, a method of manufacturing the sputtering target provided with the target material 1 having the above-described structure is described based on a flowchart of FIG. 3.

First, prior to a step 101, barium titanate (BaTiO₃) powder whose composition ratio is Ba:Ti=1:1 is prepared. The method of fabricating barium titanate (BaTiO₃) powder is not limited, and the barium titanate (BaTiO₃) powder may be produced by typical methods such as a solid-phase method, an oxalic acid method, a hydrothermal method, and a sol-gel method. For example, the barium titanate (BaTiO₃) powder is formed in such a manner that barium carbonate (BaCO₃) powder and titanium oxide (TiO₂) powder are mixed, and then the mixture is calcined at temperature of about 1000° C.

Incidentally, the composition ratio of the barium titanate (BaTiO₃) powder described above is not limited to Ba:Ti=1:1 as long as the effects of the present technology are obtainable.

(Step 101: Primary Firing of BaTiO₃ Powder)

Next, the prepared barium titanate (BaTiO₃) powder is subjected to primary firing in an atmosphere containing oxygen (step 101). For example, the primary firing may be performed in air atmosphere under the condition of the temperature of 1000 to 1200° C. and the retention time of three hours. At this time, it is characterized that the barium titanate powder is actively oxidized not in vacuum but in air atmosphere containing oxygen. In addition, it is not limited to the atmosphere as long as the atmosphere contains oxygen.

(Step 102: Mixture of Additives)

After that, an additive containing manganese (Mn) is mixed with the primary-fired barium titanate (BaTiO₃) powder (step 102). At this time, the additive is mixed so that the ratio of manganese (Mn) is 0.25 atm % or lower with respect to the total amount of barium (Ba) and titanium (Ti) that configure the barium titanate (BaTiO3) powder. In addition, for example, manganese oxide (Mn₂O₃) powder is used for the additive containing manganese (Mn) as oxide of manganese. The method of fabricating manganese oxide (Mn₂O₃) is not limited, and for example, may be produced by calcining manganese carbonate (MnCO₃) at 600° C. in air atmosphere.

The additive to be mixed may preferably contain elements whose oxide production free energy near hot pressing temperature is equivalent to or greater than that of barium oxide or of titanium oxide, in consideration of oxygen desorption characteristics at the time of hot pressing.

As the additive satisfying such a condition, oxides of manganese may be preferably used, in particular, Mn₂O₃ is preferable; however a single substance or an oxide of other elements described below may be used. For example, as an additive containing manganese (Mn), MnO, MnO₂, or Mn₃O₄ may be used. Alternatively, as an additive containing silicon (Si), SiO or SiO₂ may be used. As an additive containing aluminum (Al), α-Al₂O₃ may be used. As an additive containing magnesium (Mg), MgO may be used. As an additive containing vanadium (V), V₂O₃, V₂O₄, or V₂O₅ may be used. As an additive containing tantalum (Ta), Ta₂O₅ or TaO₂ may be used. As an additive containing niobium (Nb), NbO, NbO₂, Nb₂O₃ or Nb₂O₅ may be used. As an additive containing chromium (Cr), Cr₂O₃ may be used. Further, a plurality of these additives may be used together.

(Step 103: Hot Pressing)

Subsequently, the barium titanate (BaTiO₃) powder mixed with the additives after the primary firing is hot pressed (step 103). At this time, for example, the hot pressing is performed in air atmosphere at pressure of 150 kgf/cm² and the temperature of 1270 to 1340° C. Incidentally, the hot pressing is not necessarily performed in air atmosphere, and may be performed in vacuum or in an inert gas.

The detail of the hot pressing is described below.

First, a cylindrical inner mold is set in a cylindrical outer mold. Further, a lower punch and a plate-like spacer are set in order from lower side in the inner mold. Subsequently, the barium titanate powder is put on the spacer, and then is leveled without any space. Then, a spacer and an upper punch are set in order on the barium titanate powder. Moreover, in the case where a plurality of sintered materials are fabricated, a spacer and the barium titanate powder are repeatedly stacked between the pair of upper punch and lower punch. At this time, the setting is performed so that the barium titanate powder is arranged at the center in the axial direction of the inner mold.

The barium titanate powder is molded into a plate shape by being sandwiched between the pair of plate-like spacers. In addition, since the space is substantially eliminated between the spacer and the inner mold and between the punch and the inner mold, the barium titanate powder is placed in a state of little contacting with the outside air. In other words, the barium titanate powder is placed in a substantially airtight state.

Subsequently, the outer mold set with the barium titanate powder as described above is loaded on a hot pressing apparatus so as to be in a predetermined state. Then, a pressure ram in the apparatus presses the punch in the axial direction of the outer mold and the outer mold is heated. In this way, the hot pressing is performed on the barium titanate (BaTiO₃) powder through pressing and heating, to fabricate the barium titanate (BaTiO_{3-X}) sintered material.

After the hot pressing is finished, the pressure ram is released, the barium titanate sintered material with the outer mold is taken out from the hot pressing apparatus and is gradually cooled, and is further cooled to near the room temperature. At this time, the barium titanate sintered material is not taken out from the outer mold until completion of cooling, and thus the substantially airtight state of the barium titanate sintered material is maintained.

By the above-described steps, the barium titanate (BaTiO_{3-X}) sintered material is fabricated from the barium titanate (BaTiO₃) powder to obtain the target material 1. As a result, the target material 1 has characteristics that the generation density of the crystal grain aggregate 12 having a grain diameter of 10 μm or more on the cleavage surface is less than 0.2 piece/cm².

Note that mixing of the additives at the step 102 may be omitted. In this case, after the primary firing at the step 101, the hot pressing at the step 103 is performed.

### <1-3. Effects of First Embodiment>

The sputtering target of the first embodiment described above has the conductive target material 1 with the generation density of the crystal grain aggregate on the cleavage surface of less than 0.2 piece/cm². In the sputtering target, the number of crystal grain aggregates that cause occurrence of arcing, damage of the target material, and the like in the low-frequency sputtering is extremely small, and there are few crystal grain aggregates. Therefore, it is possible to prevent occurrence of arcing, damage of the target material, and the like when the sputtering target is used in the low-frequency sputtering. In this way, the sputtering target of the embodiment of the present technology is applicable to the low-frequency sputtering.

Moreover, when the sputtering target of the first embodiment is used in the high-frequency sputtering, it is possible to improve a sputter rate as compared with an insulating target material.

Further, the sputtering target of the first embodiment contains manganese (Mn). As will be described later in Examples, adding manganese in the process of manufacturing the sputtering target more effectively suppresses generation of the crystal grain aggregate. As a result, it is possible to prevent occurrence of arcing, damage of the target material, and the like when the sputtering target containing manganese is used in the low-frequency sputtering. Further, manganese is an element effective to improve electric characteristics of dielectric substance. Therefore, a dielectric film formed by sputtering has favorable characteristics due to the sputtering using the sputtering target containing manganese.

Moreover, in the sputtering target of the first embodiment, variation in resistivity is within ±10% in the thickness direction. In other words, the composition of the target material 1 is not varied in the surface and the inside of the target material 1 and is uniform, and the oxygen deficient state is sufficient not only on the surface but also in the inside, in the thickness direction of the target material 1. When such a sputtering target is used in sputtering, a film having uniform film composition without temporal change is allowed to be formed by sputtering.

In addition, in the method of manufacturing the sputtering target of the first embodiment, the barium titanate (BaTiO₃) powder is subjected to the primary firing in air atmosphere before the hot pressing. By the primary firing in air atmosphere containing oxygen in this way, the crystal surface of the barium titanate powder is oxidized and inactivated, and thus the state of the crystal is stabilized. Accordingly, the barium titanate powder is prevented from partially melting and being recrystallized at the time of hot pressing. Further, crystallinity of the barium titanate powder is improved by the primary firing in air atmosphere. As a result, generation of the crystal grain aggregate at the time of hot pressing is allowed to be suppressed, and the barium titanate sintered material containing little crystal grain aggregates is allowed to be fabricated as a target material.

Moreover, in the method of manufacturing the sputtering target of the first embodiment, the hot pressing is allowed to be performed in air atmosphere. Accordingly, as will be described later in Examples, as compared with the case where the hot pressing is performed in vacuum, time for vacuuming is unnecessary and the time for the hot pressing step is shortened. As a result, it is possible to improve manufacturing efficiency.

### 2. Second Embodiment

### Method of Manufacturing Barium Titanate Thin Film

Next, a method of manufacturing a barium titanate thin film according to a second embodiment is described.

In the method of manufacturing the barium titanate thin film according to the second embodiment, sputtering film formation is performed with use of the sputtering target described in the first embodiment. The target material included in the sputtering target has conductivity and the generation density of the crystal grain aggregate of 0.2 piece/cm², and thus it is possible to prevent occurrence of arcing, damage of the target material, and the like when the sputtering target is used in the low-frequency sputtering. Accordingly, in the sputtering film formation with use of the sputtering target, a low-frequency power source is allowed to be used without limitation to a high-frequency power source, or a power source that is combined with low frequency and high frequency may be used. Moreover, sputtering film formation by a roll to roll type sputtering apparatus is possible. Further, a large sputtering apparatus to fabricate a flat panel display (FPD) is allowed to be used to manufacture a barium titanate thin film that is a dielectric film.

(Effects of Second Embodiment)

In the method of manufacturing the barium titanate thin film of the second embodiment described above, the sputtering film formation is performed with use of the sputtering target described in the first embodiment. Therefore, the barium titanate thin film is allowed to be manufactured stably by the low-frequency sputtering.

### 3. Third Embodiment

### Method of Manufacturing Thin Film Capacitor

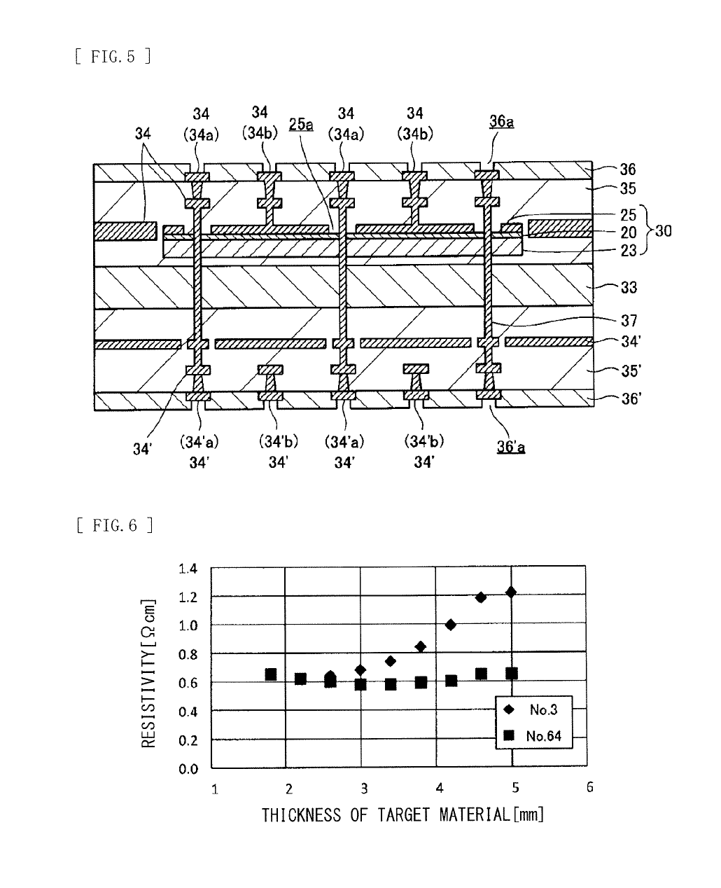

Next, a method of manufacturing a thin film capacitor according to a third embodiment is described. FIG. 4 is a diagram illustrating a thin film capacitor fabricated in the third embodiment. FIG. 5 is a diagram illustrating a circuit substrate incorporated with the thin film capacitor illustrated in FIG. 4.

In the method of manufacturing a thin film capacitor 30 according to the third embodiment, first, a barium titanate thin film 20 is formed on a first electrode 23 by the sputtering film formation with use of the sputtering target described in the first embodiment, and then a second electrode 25 is formed on the barium titanate thin film 20.

In this way, as illustrated in FIG. 4, the thin film capacitor 30 having a structure in which the barium titanate thin film 20 is sandwiched between the first electrode 23 and the second electrode 25 opposite to each other is fabricated. Here, the first electrode 23 illustrated in FIG. 4 may be a metal foil formed of, for example, nickel. The second electrode 25 may have, for example, a two-layer structure, and is configured of a nickel layer 25-1 provided on the barium titanate thin film 20, and a copper layer 25-2 provided thereon.

For example, the thin film capacitor 30 fabricated in the above-described manufacturing method may be incorporated in a circuit substrate and used.

As illustrated in FIG. 5, in the circuit substrate that is a double-sided substrate, an interlayer insulating film 35 is provided on a first surface of a substrate 33, and the thin film capacitor 30 is embedded in the interlayer insulating film 35. In addition, an electrode layer 34 (34a and 34b) is provided in and on the interlayer insulating film 35. The electrode layers 34 in respective layers are mutually connected to one another through via, and parts of the electrode layer 34 (34b) is connected to the second electrode 25 of the thin film capacitor 30. Further, the interlayer insulating film 35 is covered with a protective insulating film 36. The protective insulating film 36 has a hole 36a corresponding to the electrode layer 34 (34a and 34b) on the interlayer insulating film 35.

On the other hand, an interlayer insulating film 35′ is provided on a second surface of the substrate 33. Moreover, an electrode layer 34′ (34′a and 34′b) is provided in and on the interlayer insulating film 35′, and parts of the electrode layers 34′ in respective layers are mutually connected to one another through via. Further, the interlayer insulating film 35′ is covered with a protective insulating film 36′. The protective insulating film 36′ has a hole 36′a corresponding to the electrode layer 34 (34′a and 34′b) on the interlayer insulating film 35′.

Further, a through via 37 is provided to penetrate the substrate 33, and connects the electrode layer 34 on the first surface side of the substrate 33 with the electrode layer 34′ on the second surface side of the substrate 33. Further, the through via 37 connects a part of the electrode layer 34 (34a) and the electrode layer 34′ (34′a) with the first electrode 23 of the thin film capacitor 30. Moreover, the second electrode 25 of the thin film capacitor 30 has a hole 25a that has a diameter one size larger than that of the through via 37, and the through via 37 passes through the hole 25a.

In addition, the first electrode 23 and the second electrode 25 of the thin film capacitor 30 are electrically insulated from each other, and are connected to the electrode layers 34 (34a and 34b) different from each other. The electrode layer 34 (34a) on the interlayer insulating film 35 is connected to the first electrode 23 through the via and the through via 37, and is an extract section of the first electrode 23. On the other hand, the electrode layer 34 (34b) on the interlayer insulating film 35 is connected to the second electrode 25 through the via, and is an extract section of the second electrode 25. Further, similarly on the interlayer insulating film 35′, the electrode layer 34′ (34′a) is connected to the first electrode 23, the electrode 34′ (34′b) is connected to the second electrode 23 (not illustrated), and are extract sections of the respective electrodes. These electrode layers 34 (34a and 34b) and 34′ (34′a and 34′b) serve as external terminals of the thin film capacitor 30, and are connected to external devices to drive the thin film capacitor 30.

<Effects of Third Embodiment>

In the method of manufacturing the thin film capacitor according to the third embodiment as described above, the sputtering film formation is performed with use of the sputtering target described in the first embodiment. Therefore, it is possible to manufacture a barium titanate thin film stably by the low-frequency sputtering. As a result, it is applicable to a large sputtering apparatus using a low-frequency power source, and a thin film capacitor using a large substrate is allowed to be manufactured.

### Example 1

### Fabrication of Target Material

As will be described below, target material samples 1 to 92 were fabricated. A size of each of the target materials was 200 mm in diameter, and 5 mm in thickness.

In the samples 1 to 17, the target materials were fabricated without mixing additives.

On the other hand, in the samples 18 to 92, the target materials were fabricated by mixing manganese oxide (Mn₂O₃) as an additive. Among them, in the samples 18 to 41, manganese oxide (Mn₂O₃) was mixed so that the ratio of manganese (Mn) with respect to the total amount of barium (Ba) and titanium (Ti) that configured the barium titanate (BaTiO₃) powder was 0.05%. Manganese oxide (Mn₂O₃) was mixed so that the above-described ratio of manganese was 0.15% in the samples 42 to 76, and the above-described ratio of manganese was 0.25% in the samples 77 to 92.

In the following Tables 1A to 4A, fabrication conditions of the respective samples are illustrated for each additive amount of manganese (Mn). The detail of fabrication procedure of each sample will be described below based on the Tables.

TABLE 1A
Mn: None

| | Primary | Hot | | | | |
|---|---|---|---|---|---|---|
| | Firing | Pressing | | | | Suitable |
| | Tem- | Tem- | Crystal | | | Range of |
| Sample | perature | perature | Grain | Resis- | Den- | Present |
| No. | (° C.) | (° C.) | Aggregate | tivity | sity | Technology |
| 1 | None | 1280 | Circle | Cross | Circle | |
| 2 | | 1290 | Cross | Circle | Circle | |
| 3 | 950 | 1280 | Circle | Cross | Circle | |
| 4 | | 1290 | Cross | Circle | Circle | |
| 5 | 1000 | 1280 | Circle | Circle | Circle | Double |
| | | | | | | Circle |
| 6 | | 1290 | Cross | Circle | Circle | |
| 7 | 1050 | 1280 | Circle | Circle | Circle | Double |
| | | | | | | Circle |
| 8 | | 1290 | Cross | Circle | Circle | |
| 9 | 1100 | 1280 | Circle | Circle | Circle | Double |
| | | | | | | Circle |
| 10 | | 1290 | Cross | Circle | Circle | |
| 11 | 1150 | 1280 | Circle | Circle | Circle | Double |
| | | | | | | Circle |
| 12 | | 1290 | Circle | Circle | Circle | Double |
| | | | | | | Circle |
| 13 | | 1300 | Cross | Circle | Circle | |
| 14 | 1200 | 1280 | Circle | Circle | Cross | |
| 15 | | 1290 | Circle | Circle | Cross | |
| 16 | | 1300 | Circle | Circle | Cross | |
| 17 | | 1310 | Cross | Circle | Circle | |

TABLE 2A
Mn: 0.05%

| | Primary | Hot | | | | |
|---|---|---|---|---|---|---|
| | Firing | Pressing | | | | Suitable |
| | Tem- | Tem- | Crystal | | | Range of |
| Sample | perature | perature | Grain | Resis- | Den- | Present |
| No. | (° C.) | (° C.) | Aggregate | tivity | sity | Technology |
| 18 | None | 1280 | Circle | Cross | Circle | |
| 19 | | 1290 | Circle | Cross | Circle | |
| 20 | 950 | 1280 | Circle | Cross | Circle | |
| 21 | | 1290 | Circle | Cross | Circle | |
| 22 | 1000 | 1280 | Circle | Cross | Circle | |
| 23 | | 1290 | Circle | Circle | Circle | Double |
| | | | | | | Circle |
| 24 | | 1300 | Cross | Circle | Circle | |
| 25 | 1050 | 1280 | Circle | Cross | Circle | |
| 26 | | 1290 | Circle | Circle | Circle | Double |
| | | | | | | Circle |
| 27 | | 1300 | Cross | Circle | Circle | |
| 28 | 1100 | 1280 | Circle | Cross | Circle | |
| 29 | | 1290 | Circle | Circle | Circle | Double |
| | | | | | | Circle |
| 30 | | 1300 | Circle | Circle | Circle | Double |
| | | | | | | Circle |
| 31 | | 1310 | Cross | Circle | Circle | |
| 32 | 1150 | 1280 | Circle | Cross | Circle | |
| 33 | | 1290 | Circle | Circle | Circle | Double |
| | | | | | | Circle |
| 34 | | 1300 | Circle | Circle | Circle | Double |
| | | | | | | Circle |
| 35 | | 1310 | Circle | Circle | Circle | Double |
| | | | | | | Circle |
| 36 | | 1320 | Cross | Circle | Circle | |
| 37 | 1200 | 1280 | Circle | Cross | Cross | |
| 38 | | 1290 | Circle | Circle | Cross | |
| 39 | | 1300 | Circle | Circle | Cross | |
| 40 | | 1310 | Circle | Circle | Circle | Double |
| | | | | | | Circle |
| 41 | | 1320 | Cross | Circle | Circle | |

TABLE 3A
Mn: 0.15%

| | Primary | Hot | | | | |
|---|---|---|---|---|---|---|
| | Firing | Pressing | | | | Suitable |
| | Tem- | Tem- | Crystal | | | Range of |
| Sample | perature | perature | Grain | Resis- | Den- | Present |
| No. | (° C.) | (° C.) | Aggregate | tivity | sity | Technology |
| 42 | None | 1290 | Circle | Cross | Circle | |
| 43 | | 1300 | Cross | Cross | Circle | |
| 44 | | 1310 | Cross | Cross | Circle | |
| 45 | | 1320 | Cross | Cross | Circle | |
| 46 | | 1330 | Cross | Circle | Circle | |
| 47 | 950 | 1290 | Circle | Cross | Circle | |
| 48 | | 1300 | Cross | Cross | Circle | |
| 49 | | 1310 | Cross | Cross | Circle | |
| 50 | | 1320 | Cross | Cross | Circle | |
| 51 | | 1330 | Cross | Circle | Circle | |
| 52 | 1000 | 1290 | Circle | Cross | Circle | |
| 53 | | 1300 | Circle | Circle | Circle | Double |
| | | | | | | Circle |
| 54 | | 1310 | Circle | Circle | Circle | Double |
| | | | | | | Circle |
| 55 | | 1320 | Cross | Circle | Circle | |
| 56 | | 1330 | Cross | Circle | Circle | |
| 57 | 1050 | 1290 | Circle | Cross | Circle | |
| 58 | | 1300 | Circle | Circle | Circle | Double |
| | | | | | | Circle |
| 59 | | 1310 | Circle | Circle | Circle | Double |
| | | | | | | Circle |
| 60 | | 1320 | Circle | Circle | Circle | Double |
| | | | | | | Circle |
| 61 | | 1330 | Cross | Circle | Circle | |
| 62 | 1100 | 1290 | Circle | Cross | Circle | |
| 63 | | 1300 | Circle | Circle | Circle | Double |
| | | | | | | Circle |
| 64 | | 1310 | Circle | Circle | Circle | Double |
| | | | | | | Circle |
| 65 | | 1320 | Circle | Circle | Circle | Double |
| | | | | | | Circle |
| 66 | | 1330 | Cross | Circle | Circle | |
| 67 | 1150 | 1290 | Circle | Cross | Circle | |
| 68 | | 1300 | Circle | Circle | Circle | Double |
| | | | | | | Circle |
| 69 | | 1310 | Circle | Circle | Circle | Double |
| | | | | | | Circle |
| 70 | | 1320 | Circle | Circle | Circle | Double |
| | | | | | | Circle |
| 71 | | 1330 | Cross | Circle | Circle | |
| 72 | 1200 | 1290 | Circle | Cross | Cross | |
| 73 | | 1300 | Circle | Circle | Cross | |
| 74 | | 1310 | Circle | Circle | Circle | Double |
| | | | | | | Circle |
| 75 | | 1320 | Circle | Circle | Circle | Double |
| | | | | | | Circle |
| 76 | | 1330 | Cross | Circle | Circle | |

TABLE 4A
Mn: 0.25%

| | Primary | Hot | | | | |
|---|---|---|---|---|---|---|
| | Firing | Pressing | | | | Suitable |
| | Tem- | Tem- | Crystal | | | Range of |
| Sample | perature | perature | Grain | Resis- | Den- | Present |
| No. | (° C.) | (° C.) | Aggregate | tivity | sity | Technology |
| 77 | 1050 | 1320 | Circle | Cross | Circle | |
| 78 | | 1330 | Circle | Cross | Circle | |
| 79 | | 1340 | Circle | Cross | Circle | |
| 80 | 1100 | 1320 | Circle | Cross | Circle | |
| 81 | | 1330 | Circle | Circle | Circle | Double |
| | | | | | | Circle |
| 82 | | 1340 | Circle | Circle | Circle | Double |
| | | | | | | Circle |
| 83 | | 1350 | Cross | Circle | Circle | |
| 84 | 1150 | 1320 | Circle | Cross | Circle | |
| 85 | | 1330 | Circle | Circle | Circle | Double |
| | | | | | | Circle |
| 86 | | 1340 | Circle | Circle | Circle | Double |
| | | | | | | Circle |
| 87 | | 1350 | Cross | Circle | Circle | |
| 88 | 1200 | 1320 | Circle | Cross | Circle | |
| 89 | | 1330 | Circle | Circle | Circle | Double |
| | | | | | | Circle |
| 90 | | 1340 | Circle | Circle | Circle | Double |
| | | | | | | Circle |
| 91 | | 1350 | Circle | Circle | Circle | Double |
| | | | | | | Circle |
| 92 | | 1360 | Cross | Circle | Circle | |

(Fabrication Procedure of Target Material Samples 1 and 2)

The fabrication procedure of the target material samples 1 and 2 is described (see Table 1A). In this case, only the hot pressing at the step 103 in the flow illustrated in FIG. 3 used for previous description of the first embodiment is performed.

First, the barium titanate (BaTiO₃) powder whose composition ratio was Ba:Ti=1:1 was prepared.

Then, as described in the first embodiment, the barium titanate (BaTiO₃) powder was put in the mold, and the mold was set in the hot pressing apparatus. Then, the hot pressing was performed in air atmosphere at pressure of 150 kgf/cm² and at each temperature (1280° C. and 1290° C.) illustrated in Table 1A. At this time, after pressurizing and heating were started and after the temperature reached to the set temperature, displacement of the pressure ram was stopped. Then, after 10 minutes from the time, the pressure of the pressure ram was released over 30 minutes. When the pressure release was completed, the retention of the set temperature was ended.

After that, the barium titanate sintered material with the mold was taken out from the hot pressing apparatus and was gradually cooled, and was further cooled to near the room temperature. After the cooling was completed, the barium titanate sintered material was taken out from the mold, and facing process was performed thereon to obtain the target material having a diameter of 200 mm and a thickness of 5 mm.

(Fabrication Procedure of Target Material Samples 3 to 17)

The fabrication procedure of the target material samples 3 to 17 is different from the fabrication procedure of the target material samples 1 and 2 in that the primary firing is performed before the hot pressing (see Table 1A). In other words, the primary firing at the step 101 and the hot pressing at the step 103 in the flow illustrated in FIG. 3 are performed.

First, the barium titanate (BaTiO₃) powder whose composition ratio was Ba:Ti=1:1 was prepared.

Subsequently, the barium titanate (BaTiO₃) powder was put in an alumina sheath with purity of 99.7%, and the primary firing was performed in air atmosphere under the condition of each temperature (950 to 1200° C.) illustrated in Table 1A and the retention time of three hours.

Thereafter, as with the samples 1 and 2, the primary-fired barium titanate (BaTiO₃) powder was put in the mold, and the mold was set in the hot pressing apparatus. Then, the hot pressing was performed in air atmosphere at pressure of 150 kgf/cm² and at each temperature (1280 to 1310° C.) illustrated in Table 1A.

After that, the barium titanate sintered material with the mold was taken out from the hot pressing apparatus and was gradually cooled, and was further cooled to near the room temperature. After the cooling was completed, the barium titanate sintered material was taken out from the mold, and the facing process was performed thereon to obtain the target material having a diameter of 200 mm and a thickness of 5 mm.

(Fabrication Procedure of Target Material Samples 18, 19, and 42 to 46) The fabrication procedure of the target material samples 18, 19, and 42 to 46 is different from the fabrication procedure of the target material samples 1 and 2 in that manganese is mixed before the hot pressing (see Tables 2A and 3A). In other words, the mixing of additives at the step 102 and the hot pressing at the step 103 in the flow illustrated in FIG. 3 are performed.

First, the barium titanate (BaTiO₃) powder whose composition ratio was Ba:Ti=1:1 was prepared.

Next, the barium titanate (BaTiO₃) powder was mixed with manganese oxide (Mn₂O₃) powder. At this time, weighing was performed so that a ratio of Mn with respect to the total amount of Ba and Ti was made to be predetermined ratio (0.05 atm % and 0.15 atm %), and the mixing was performed by a wet ball mill for eight hours, followed by drying. As a result, the barium titanate (BaTiO₃) powder mixed with manganese oxide was obtained.

Thereafter, as with the samples 1 and 2, the barium titanate (BaTiO₃) powder mixed with manganese oxide was put in the mold, and the mold was set in the hot pressing apparatus. Then, the hot pressing was performed in air atmosphere at pressure of 150 kgf/cm2 and at each temperature (1280 to 1330° C.) illustrated in Table 2A or 3A.

After that, the barium titanate sintered material containing manganese with the mold was taken out from the hot pressing apparatus and was gradually cooled, and was further cooled to near the room temperature. After the cooling was completed, the barium titanate sintered material was taken out from the mold, and the facing process was performed thereon to obtain the target material having a diameter of 200 mm and a thickness of 5 mm.

(Fabrication Procedure of Target Material Samples 20 to 41, and 47 to 92) The fabrication procedure of the target material samples 20 to 41, and 47 to 92 is different from the fabrication procedure of the target material samples 1 and 2 in that the primary firing is performed before the hot pressing and manganese is mixed (see Tables 2A, 3A, and 4A). In other words, the primary firing at the step 101, the mixing of additives at the step 102, and the hot pressing at the step 103 are performed as illustrated in the flowchart of FIG. 3.

First, the barium titanate (BaTiO₃) powder whose composition ratio was Ba:Ti=1:1 was prepared.

Subsequently, the barium titanate (BaTiO₃) powder was put in an alumina sheath with purity of 99.7%, and the primary firing was performed in air atmosphere under the condition of each temperature (950 to 1200° C.) illustrated in Table 2A, 3A, or 4A, and the retention time of three hours.

After that, the primary-fired barium titanate (BaTiO₃) powder was mixed with manganese oxide (Mn₂O₃). At this time, weighing was performed so that a ratio of Mn with respect to the total amount of Ba and Ti was made to be predetermined ratio (0.05 atm % and 0.15 atm %), and the mixing was performed by a wet ball mill for eight hours, followed by drying. As a result, the barium titanate (BaTiO₃) powder mixed with manganese oxide was obtained.

Thereafter, as with the samples 1 and 2, the primary-fired barium titanate (BaTiO₃) powder mixed with manganese oxide was put in the mold, and the mold was set in the hot pressing apparatus. Then, the hot pressing was performed in air atmosphere at pressure of 150 kgf/cm² and at each temperature (1280 to 1360° C.) illustrated in Table 2A, 3A, or 4A.

After that, the barium titanate sintered material containing manganese with the mold was taken out from the hot pressing apparatus and was gradually cooled, and was further cooled to near the room temperature. After the cooling was completed, the barium titanate sintered material was taken out from the mold, and the facing process was performed thereon to obtain the target material having a diameter of 200 mm and a thickness of 5 mm.

### Evaluation of Example 1

As for the target material samples 1 to 92 fabricated as above, three conditions of generation density of crystal grain aggregate, resistivity, and density of target material were examined as described below.

(1) Generation Density of Crystal Grain Aggregate

Half of the target materials were cleft more than once in a random manner, and the plurality of pairs of cleavage surfaces were observed over the range of about 50 cm² by a stereoscopic microscope at a magnification of 50 times or 100 times. At this time, only one of the pair of cleavage surfaces generated by cleaving was observed. As a result of the above-described observation, the sample at which the generation density of the crystal grain aggregate having a grain diameter of 10 to 80 μm was less than 0.2 piece/cm² was determined as suitable (circle), and others were determined as unsuitable (cross).

(2) Resistivity

The resistivity of the target material was measured with use of a four probe method. The sample at which the resistivity was within the range of 0.1 to 10 Ωcm and the variation of the resistivity in the thickness direction of the target material was within ±10% was determined as suitable (circle), and others were determined as unsuitable (cross).

(3) Density of Target Material

The volume and the weight of the target material were measured, and the sample at which the density calculated therefrom was equal to or larger than 95% was determined as suitable (circle), and others were determined as unsuitable (cross).

The evaluation results of the above-described three items are illustrated in the following Tables 1B to 4B. Note that, in the Table 1B to 4B, a column direction indicates primary firing temperature, a row direction indicates hot pressing temperature, and the evaluation result is illustrated in a frame where both directions intersect. The Tables 1B to 4B illustrate the same samples as the Tables 1A to 4A, respectively.

TABLE 1B

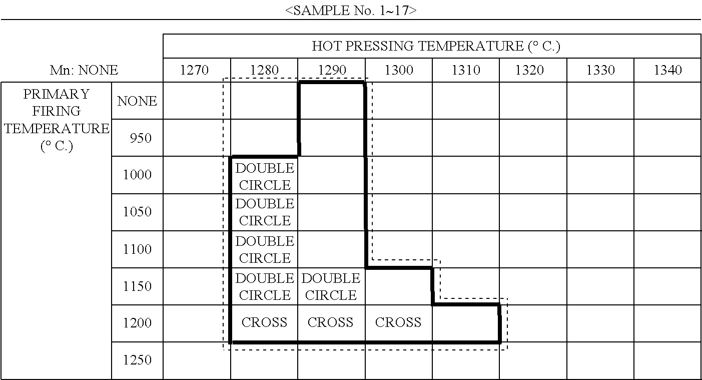

NOTE:

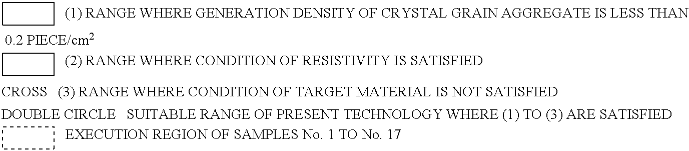

TABLE 2B

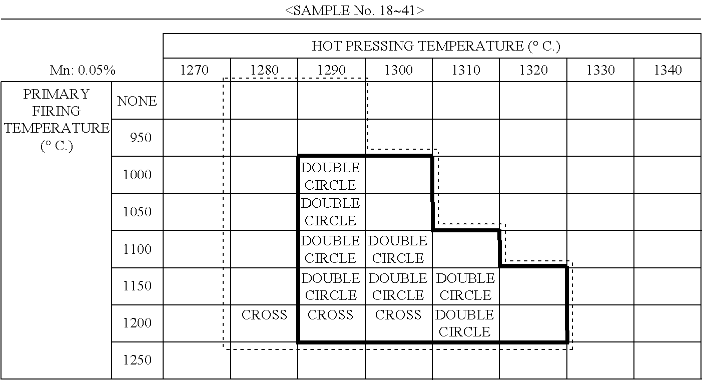

NOTE:

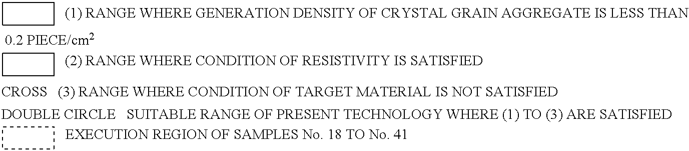

TABLE 3B

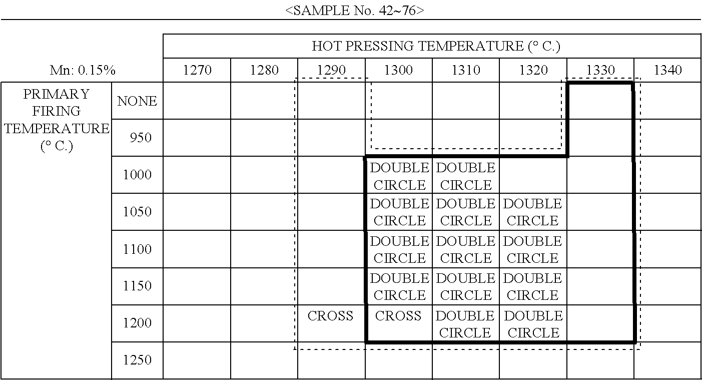

NOTE:

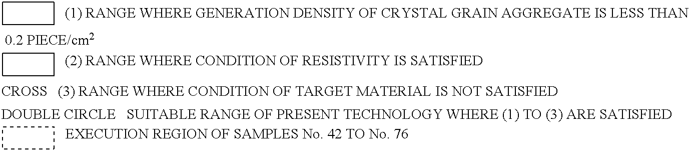

TABLE 4B

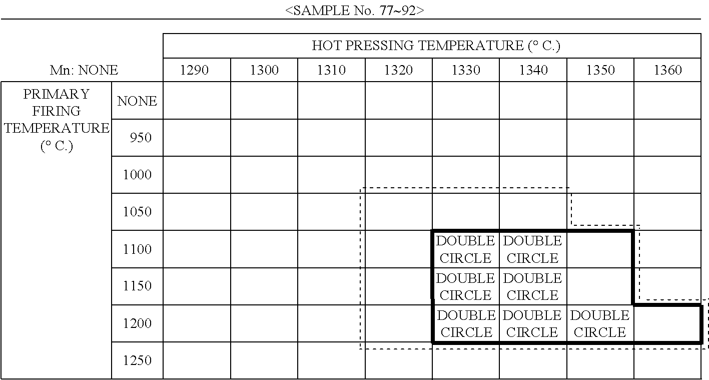

NOTE:

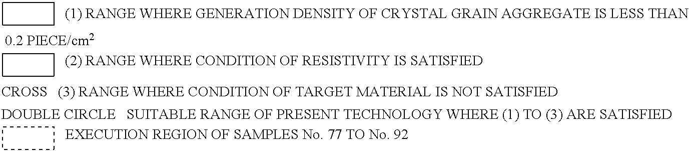

<Evaluation Results of Example 1>

As is obvious from the Table 1B to 4B, in the range of the primary firing temperature up to 1200° C., the range of the hot pressing temperature satisfying (1) generation density of crystal grain aggregate is wider and the range of the hot pressing temperature satisfying (2) resistivity is also wider, as the primary firing temperature is higher. Further, the range of the hot pressing temperature satisfying both of (1) generation density of crystal grain aggregate and (2) resistivity is wider as the primary firing temperature is higher.

Moreover, as is obvious from the Table 1B to 3B, in the condition of no primary firing or in the condition of the primary firing temperature of 950° C., the condition of the hot pressing temperature satisfying both of (1) generation density of crystal grain aggregate and (2) resistivity is not present. Therefore, the primary firing may be preferably performed at temperature higher than 950° C.

Moreover, as is obvious from the Table 1B to 4B, in the Table 1B (no manganese added), the hot pressing temperature satisfying all of (1) generation density of crystal grain aggregate, (2) resistivity, and (3) density of target material is within the range of 1280 to 1290° C. (primary firing: 1150° C.). In the Table 2B (manganese: 0.05 atm %), the hot pressing temperature satisfying all of (1) to (3) described above is within the range of 1290 to 1310° C. (primary firing: 1150° C.). In the Table 3B (manganese: 0.15 atm %), the hot pressing temperature satisfying all of (1) to (3) described above is within the range of 1300 to 1320° C. (primary firing: 1050 to 1150° C.). In the Table 4B (manganese: 0.25 atm %), the hot pressing temperature satisfying all of (1) to (3) described above is within the range of 1330 to 1350° C. (primary firing: 1200° C.). Therefore, in the confirmed range of manganese content of 0.25 atm % or lower, the range of the hot pressing temperature after the primary firing, namely, the range of proper temperature is expanded by addition of manganese (Mn2O3). In this case, in the hot pressing apparatus, typically, it is not unusual that an error of about 10° C. occurs between the temperature displayed on the apparatus and the actual temperature of the sintered material. Therefore, when such a hot pressing apparatus difficult in adjustment of the actual temperature of the sintered material is used, adding manganese oxide (Mn₂O₃) expands the range of the hot pressing temperature, which makes it easy to manufacture the target material.

Moreover, as is obvious from the Table 1B to 4B, when manganese oxide (Mn₂O₃) is added so that the content of manganese (Mn) is made to be lower than 0.25 atm % (corresponding to the Tables 2B and 3B), the range of the primary firing temperature and the range of the hot pressing temperature that satisfy both of (1) generation density of crystal grain aggregate and (2) resistivity are both expanded. The respective temperature ranges are expanded, which makes it easy to control the primary firing temperature and the hot pressing temperature, and therefore manufacturing of the target material becomes easy.

Moreover, as is obvious from the Table 1B to 3B, in the range where the content of manganese that allows the temperature range at the above-described respective steps to be expanded is lower than 0.25 atm %, when the primary firing temperature is at 1200° C., there is a sample not satisfying the condition of (3) density of target material. Therefore, when the primary firing is performed at temperature lower than 1200° C., it is possible to obtain the target material that satisfies all of the above-described conditions (1) to (3) with the wide range of the hot pressing temperature.

Further, as an example, as for the target material samples 3 and 64, variation in resistivity in the thickness direction of the target material is illustrated in FIG. 6. In the target material sample 3, although the resistivity is within the range of 0.1 to 10 Ωcm, the resistivity changes from the surface having the thickness of 1 mm toward the surface having the thickness of 5 mm, and is varied about ±30%. The target material sample 3 was determined as unsuitable (cross). On the other hand, in the target material sample 64, the resistivity is within the range of 0.1 to 10 Ωcm and the resistivity is hardly varied from the surface having the thickness of 1 mm toward the surface having the thickness of 5 mm. The target material sample 64 was determined as suitable (circle).

Note that, in each of the Tables 1B to 4B, all of the execution regions of the experiment are surrounded by a dashed line. In the range other than the range surrounded by the dashed line, both of (1) generation density of crystal grain aggregate and (2) resistivity are not satisfied, and therefore, its results are not illustrated in the table. Moreover, when the primary firing temperature exceeds 1200° C., necking force between the fired barium titanate powders is strengthened and subsequent disintegrating is difficult, and therefore, its results are not illustrated in the table.

### Comparative Example 1

### Fabrication of Target Material

In a comparative example 1, a target material was fabricated by mixing an additive before the primary firing. The fabrication of the target material was performed in a manner similar to that in the Example 1 except that the timing of mixing the additive was different from the Example 1. Fabrication conditions of the respective samples are illustrated in the following Table 5. The detail of the fabrication procedure of each sample will be described next.

(Fabrication Procedure of Target Material Samples 93 to 95)

First, before the barium titanate (BaTiO₃) powder was subjected to the primary firing, the barium titanate (BaTiO₃) powder was mixed with manganese oxide (Mn₂O₃). At this time, weighing was performed so that the ratio of Mn with respect to the total amount of Ba and Ti was made to be 0.15 atm %, and the mixing was performed by a wet ball mill for eight hours, followed by drying.

Next, the primary firing was performed at 1100° C. to obtain barium titanate (BaTiO₃) powder mixed with manganese oxide.

Thereafter, as with the samples 1 and 2 of the example 1, after the hot pressing was performed, the barium titanate sintered material with the mold was taken out from the hot pressing apparatus and was gradually cooled, and was further cooled to near the room temperature. After the cooling was completed, the barium titanate sintered material was taken out from the mold, and the facing process was performed to obtain the target material having a diameter of 200 mm and a thickness of 5 mm.

<Evaluation of Comparative Example 1>

The target material samples 93 to 95 obtained in the above-described manner were evaluated similarly to the Example 1. The results are illustrated in the following Table 5.

TABLE 5
Mn: 0.15%

| | Primary | | | | |
|---|---|---|---|---|---|
| | Firing | Hot Pressing | Crystal | | |
| Sample | Temperature | Temperature | Grain | | |
| No. | (° C.) | (° C.) | Aggregate | Resistivity | Density |
| 93 | 1100 | 1300 | Cross | Cross | Cross |
| 94 | | 1310 | Cross | Circle | Circle |
| 95 | | 1320 | Cross | Circle | Circle |

<Evaluation Results of Comparative Example 1>

The experiment results of the samples 93 to 95 in the Table 5 and the experiment results of the samples 63 to 65 in the Table 3A fabricated in the Example 1, that are different in timing of mixing the additive are compared. The samples 93 to 95 and the samples 63 to 65 are the same in terms of the temperature conditions of the primary firing and the hot pressing, and the manganese content of the target material. In the samples 93 to 95 in the Table 5 that were each mixed with manganese oxide (Mn₂O₃) before the primary firing, only (1) generation density of crystal grain aggregate was not satisfied, or all of (1) generation density of crystal grain aggregate, (2) resistivity, and (3) density of target material were not satisfied. On the other hand, in the samples 63 to 65 in the Table 3A that were different in mixing timing and were each mixed with manganese oxide (Mn₂O₃) after the primary firing, all of (1) generation density of crystal grain aggregate, (2) resistivity, and (3) density of target material were satisfied. Therefore, it was confirmed that, when manganese oxide (Mn₂O₃) is mixed not before the primary firing but after the primary firing, it is possible to fabricate the conductive target material according to the embodiment of the technology with generation density of the crystal grain aggregate of less than 0.2 piece/cm².

### Comparative Example 2

### Fabrication of Target Materials

In a comparative example 2, manganese carbonate (MnCO₃) was mixed as an additive to fabricate the target material. In the comparative example 2, the target materials were fabricated in a manner similar to the samples 63 to 65 of the Example 1 under the conditions similar to those in the Example 1 except that manganese oxide (Mn₂O₃) was used as the additive in the Example 1. Fabrication conditions of the respective samples are illustrated in the following Table 6. The detail of the fabrication procedure of each sample will be described next.

(Fabrication Procedure of Target Material Samples 96 to 98)

First, similar to the samples 63 to 65 that were in the suitable range of the present technology in the Example 1, the primary firing of the barium titanate (BaTiO₃) powder was performed at temperature of 1100° C. that was confirmed to be suitable temperature in the Example 1.

Subsequently, the fired barium titanate (BaTiO₃) powder was mixed with manganese carbonate (MnCO₃). At this time, weighing was performed so that the ratio of Mn with respect to the total amount of Ba and Ti was made to be 0.15 atm %, and the mixing was performed by a wet ball mill for eight hours, followed by drying.

Thereafter, similarly to the samples 63 to 65 in the Example 1, the hot pressing was performed at temperature of 1300 to 1320° C. that was confirmed to be suitable temperature in the Example 1. After that, the barium titanate sintered material with the mold was taken out from the hot pressing apparatus and was gradually cooled, and was further cooled to near the room temperature. After the cooling was completed, the barium titanate sintered material was taken out from the mold, and the facing process was performed to obtain the target material having a diameter of 200 mm and a thickness of 5 mm.

<Evaluation of Comparative Example 2>

The target material samples 96 to 98 obtained in the above-described manner were evaluated similarly to the Example 1. The results are illustrated in the following Table 6.

TABLE 6
Mn: 0.15%

| | Primary | | | | |
|---|---|---|---|---|---|
| | Firing | Hot Pressing | Crystal | | |
| Sample | Temperature | Temperature | Grain | | |
| No. | (° C.) | (° C.) | Aggregate | Resistivity | Density |
| 96 | 1100 | 1300 | Circle | Cross | Cross |
| 97 | | 1310 | Cross | Cross | Circle |
| 98 | | 1320 | Cross | Cross | Circle |

<Evaluation Results of Comparative Example 2>

The experiment results of the samples 96 to 98 in the Table 6 and the experiment results of the samples 63 to 65 in the Table 3A that are different in used additives from each other are compared. The samples 96 to 98 and the samples 63 to 65 are the same in terms of the temperature conditions of the primary firing and the hot pressing, and the manganese content of the target material. In the samples 96 to 98 in the Table 9 in which manganese carbonate (MnCO₃) was used as the additive, any two of (1) generation density of crystal grain aggregate, (2) resistivity, and (3) density of target material were not satisfied. On the other hand, in the samples 63 to 65 in the Table 3A in which manganese oxide (Mn₂O₃) was used as the additive in place of manganese carbonate (MnCO₃), all of (1) generation density of crystal grain aggregate, (2) resistivity, and (3) density of target material were satisfied. Accordingly, it was confirmed that, when manganese oxide (Mn₂O₃) is used as the additive in place of manganese carbonate (MnCO₃), it is possible to fabricate the conductive target material according to the embodiment of the technology with generation density of crystal grain aggregate of less than 0.2 piece/cm².

### Example 2

### Sputtering Film Formation Using Sputtering Target

As will be described below, sputtering film formation A and B are performed with use of the sputtering target having the target material sample 64 that is the conductive target material according to the embodiment of the technology with generation density of crystal grain aggregate of less than 0.2 piece/cm² and is fabricated in the Example 1.

(Sputtering Film Formation A)

First, two sputtering targets having the target material sample 64 that was fabricated in the Example 1 were prepared and were attached to a sputtering apparatus. An AC power source (50 kHz) was connected between the two sputtering targets, and argon and oxygen were adjusted so that oxygen partial pressure became 0.005 Pa. The sputtering apparatus was prepared in the above-described manner.

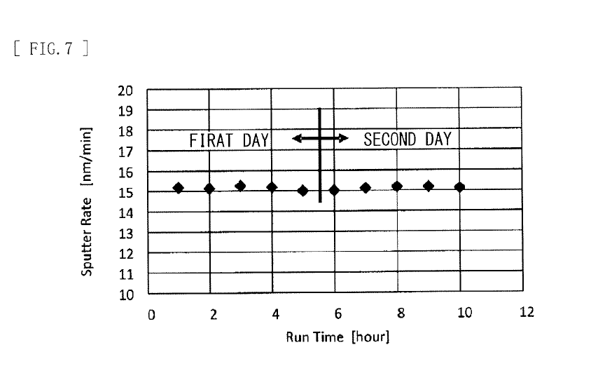

Then, the sputtering apparatus was used to discharge electricity under the condition of power density of the AC power source of 2 W/cm² and a film formation time of 30 minutes, and thus sputtering film formation was performed. The sputtering film formation was repeated in the following manner. First, on a first day, the sputtering film formation of the above-described condition was performed continuously five times, and on a second day, the similar sputtering film formation was performed continuously five times. The results are illustrated in FIG. 7.

(Sputtering Film Formation B)

Further, the sputtering film formation was repeated in a manner similar to that of the above-described sputtering film formation A except that the power density of the AC power source was changed to 5.5 W/cm². As a result, an average sputter rate of 35 nm/min was obtained.

<Evaluation Results of Example 2>

In the above-described two examples of the sputtering film formation A and B, the sputtering film formation was repeated; however, disadvantage such as occurrence of arching and damage of target material did not occur. Therefore, it was confirmed that, when the sputtering target including the target material with generation density of crystal grain aggregate of less than 0.2 piece/cm² is used, it is possible to perform sputtering film formation using the AC power source without disadvantage such as occurrence of arching and damage of target material.

Moreover, as a result of the sputtering film formation A illustrated in FIG. 7, an average sputter rate of 15 nm/min was obtained. Furthermore, as a result of the sputtering film formation B described above, an average sputter rate of 35 nm/min was obtained. Accordingly, when the sputtering target including a conductive target material is used, a high sputter rate is allowed to be obtained in the sputtering film formation using the AC power source.

Moreover, as is obvious from FIG. 7, variation of the sputter rate was smaller than ±1%. Accordingly, in the sputtering film formation using the sputtering target in which the variation in resistivity in the thickness direction of the target material is within ±10%, it is possible to perform stable sputtering film formation with high reproducibility without temporal change of a sputter rate.

### Example 3

### Fabrication of Thin Film Capacitor

As will be described below, the sputtering film formation using the sputtering target that includes the target material sample 64 fabricated in the Example 1 was performed, and the thin film capacitor 30 illustrated in FIG. 4 was fabricated.

First, a nickel (Ni) foil that is previously subjected to heat treatment and has a thickness of 50 μm was prepared, and one surface thereof was ground so that the surface roughness became Rz=0.1 μm and Ra=0.01 μm. As a result, the first electrode 23 of the thin film capacitor 30 was obtained.

Next, with use of the sputtering target including the target material sample 64 fabricated in the Example 1, the sputtering apparatus was prepared as with the Example 2, and the sputtering film formation was performed at the power density of the AC power source of 2 W/cm². At this time, the barium titanate thin film 20 having the thickness of about 500 nm was formed on the first electrode 23 of the nickel foil. Subsequently, annealing treatment was performed at 900° C.

After that, a film of nickel (Ni) was formed on the barium titanate thin film 20 by sputtering to form a nickel metal foil 24 having the thickness of 200 nm. Subsequently, a film of copper (Cu) was formed on the metal foil 24 by sputtering and plating to form the electrode layer 34 having the thickness of 5 μm. As a result, the second electrode 25 having the two-layer structure of the metal foil 24 and the electrode layer 34 was formed on the barium titanate thin film 20.

By the above-described steps, the thin film capacitor 30 illustrated in FIG. 4, having a structure in which the barium titanate thin film 20 was sandwiched between the first electrode 23 and the second electrode 25 facing to each other was obtained.

<Evaluation Results of Example 3>

It was confirmed from the above-described results that, when the sputtering target according to the embodiment of the technology is used, it is possible to perform thin film formation on a large substrate such as thin film capacitor by a large sputtering apparatus using an AC power source.

Note that the present technology may be configured as follows.

(1)

A sputtering target including a conductive barium titanate sintered material with generation density of crystal grain aggregate having a grain diameter of 10 μm or more on a cleavage surface of less than 0.2 piece/cm².

(2)

The sputtering target according to (1), wherein manganese (Mn) is contained.

(3)

The sputtering target according to (1) or (2), wherein an oxide of manganese (Mn) is contained.

(4)

The sputtering target according to (2) or (3), wherein a content of the manganese (Mn) is equal to or lower than 0.25 atm % with respect to a total amount of barium (Ba) and titanium (Ti) that configure the barium titanate sintered material.

(5)

The sputtering target according to any one of (1) to (4), wherein one or two or more elements selected from silicon (Si), aluminum (Al), magnesium (Mg), vanadium (V), tantalum (Ta), niobium (Nb), and chromium (Cr) are contained.

(6)

The sputtering target according to any one of (1) to (5), wherein oxides of one or two or more elements selected from silicon (Si), aluminum (Al), magnesium (Mg), vanadium (V), tantalum (Ta), niobium (Nb), and chromium (Cr) are contained.

(7)

The sputtering target according to any one of (1) to (6), wherein resistivity in a thickness direction is 0.1 to 10 Ω·cm, and variation of the resistivity in the thickness direction is within ±10%.

(8)

A method of manufacturing a sputtering target, the method including:

performing primary firing of barium titanate (BaTiO₃) powder in an atmosphere containing oxygen; and

performing hot pressing of fired barium titanate (BaTiO₃) powder after the primary firing.

(9)

The method of manufacturing the sputtering target according to (8), wherein the hot pressing is performed after the primary firing and after an additive containing manganese (Mn) is mixed with the fired barium titanate (BaTiO₃) powder to allow a ratio of manganese (Mn) with respect to a total amount of barium (Ba) and titanium (Ti) that configure the barium titanate (BaTiO₃) powder, to be equal to or lower than 0.25 atm %.

(10)

The method of manufacturing the sputtering target according to (9), wherein manganese oxide (Mn₂O₃) is used as the additive containing manganese (Mn).

(11)

The method of manufacturing the sputtering target according to any one of (8) to (10), wherein the hot pressing is performed in air atmosphere.

(12)

A method of manufacturing a barium titanate thin film, the method including:

preparing a sputtering target including a conductive barium titanate sintered material with generation density of crystal grain aggregate having a grain diameter of 10 μm or more on a cleavage surface of less than 0.2 piece/cm²; and

performing sputtering film formation using the sputtering target.

(13)

The method of manufacturing the barium titanate thin film according to (12), wherein in performing the sputtering film formation, a sputtering apparatus using a low-frequency power source is used.

(14)

A method of manufacturing a thin film capacitor, the method including:

forming a barium titanate thin film on a first electrode by performing sputtering film formation with use of a sputtering target, the sputtering target including a conductive barium titanate sintered material with generation density of crystal grain aggregate having a grain diameter of 10 μm or more on a cleavage surface of less than 0.2 piece/cm²; and

forming a second electrode on the barium titanate thin film.

This application is based upon and claims the benefit of priority of the Japanese Patent Application No. 2012-84057 filed in the Japan Patent Office on Apr. 2, 2012, the entire contents of this application are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A sputtering target comprising a conductive barium titanate sintered material with generation density of crystal grain aggregate having a grain diameter of 10 μm or more on a cleavage surface of less than 0.2 piece/cm².

2. The sputtering target according to claim 1, wherein manganese (Mn) is contained.

3. The sputtering target according to claim 1, wherein an oxide of manganese (Mn) is contained.

4. The sputtering target according to claim 2, wherein a content of the manganese (Mn) is equal to or lower than 0.25 atm % with respect to a total amount of barium (Ba) and titanium (Ti) that configure the barium titanate sintered material.

5. The sputtering target according to claim 1, wherein one or two or more elements selected from silicon (Si), aluminum (Al), magnesium (Mg), vanadium (V), tantalum (Ta), niobium (Nb), and chromium (Cr) are contained.

6. The sputtering target according to claim 1, wherein oxides of one or two or more elements selected from silicon (Si), aluminum (Al), magnesium (Mg), vanadium (V), tantalum (Ta), niobium (Nb), and chromium (Cr) are contained.

7. The sputtering target according to claim 1, wherein
resistivity in a thickness direction is 0.1 to 10 Ω·cm, and
variation of the resistivity in the thickness direction is within ±10%.

8. A method of manufacturing a sputtering target, the method comprising:
performing primary firing of barium titanate (BaTiO₃) powder in an atmosphere containing oxygen; and
performing hot pressing of fired barium titanate (BaTiO₃) powder after the primary firing.

9. The method of manufacturing the sputtering target according to claim 8, wherein the hot pressing is performed after the primary firing and after an additive containing manganese (Mn) is mixed with the fired barium titanate (BaTiO₃) powder to allow a ratio of manganese (Mn) with respect to a total amount of barium (Ba) and titanium (Ti) that configure the barium titanate (BaTiO₃) powder, to be equal to or lower than 0.25 atm %.

10. The method of manufacturing the sputtering target according to claim 9, wherein manganese oxide (Mn₂O₃) is used as the additive containing manganese (Mn).

11. The method of manufacturing the sputtering target according to claim 8, wherein the hot pressing is performed in air atmosphere.

12. A method of manufacturing a barium titanate thin film, the method comprising:
preparing a sputtering target including a conductive barium titanate sintered material with generation density of crystal grain aggregate having a grain diameter of 10 μm or more on a cleavage surface of less than 0.2 piece/cm²; and
performing sputtering film formation using the sputtering target.

13. The method of manufacturing the barium titanate thin film according to claim 12, wherein in performing the sputtering film formation, a sputtering apparatus using a low-frequency power source is used.

14. A method of manufacturing a thin film capacitor, the method comprising:
forming a barium titanate thin film on a first electrode by performing sputtering film formation with use of a sputtering target, the sputtering target including a conductive barium titanate sintered material with generation density of crystal grain aggregate having a grain diameter of 10 μm or more on a cleavage surface of less than 0.2 piece/cm²; and
forming a second electrode on the barium titanate thin film.
